(19) United States
(12) Patent Application Publication
(10) Pub. No.: US 2019/0259559 A1
(43) Pub. Date: Aug. 22, 2019

(54) PLASMA BRIDGE NEUTRALIZER FOR ION BEAM ETCHING

(71) Applicant: VEECO INSTRUMENTS, INC., Plainview, NY (US)

(72) Inventors: Rustam YEVTUKHOV, Plainview, NY (US); Ivan SHKURENKOV, Plainview, NY (US); Boris DRUZ, Plainview, NY (US); Alan HAYES, Plainview, NY (US); Robert HIERONYMI, Plainview, NY (US)

(21) Appl. No.: 16/270,440

(22) Filed: Feb. 7, 2019

Related U.S. Application Data
(60) Provisional application No. 62/632,984, filed on Feb. 20, 2018.

(51) Int. Cl. H01J 37/02; H01J 37/06; H01J 37/08; H01J 3/02

(52) U.S. Cl. CPC H01J 37/026; H01J 37/06; H01J 2237/0045; H01J 3/025; H01J 37/08

(57) ABSTRACT

An ion beam neutralization system, often referred to as a plasma bridge neutralizer (PBN), as part of an ion beam (etch) system. The system utilizes an improved filament thermo-electron emitter PBN design, that when utilized in a particular method of operation, greatly extends filament life and minimizes variation in neutralizer operating parameters for long periods of operation. The PBN includes a solenoidal electromagnetic that produces an axial magnetic field within the PBN and a magnetic concentrator that facilitates the alignment of the magnetic field and inhibits stray fields. The PBN can readily provide a filament lifetime of at least 500 hours.

### CROSS-REFERENCE

The present application claims priority to U.S. provisional application 62/632,984 filed Feb. 20, 2018, the entire disclosure of which is incorporated herein by reference for all purposes.

### BACKGROUND

Ion beam etching is a method of removing small (e.g., nanometer scale) amounts of material from a substrate such as a wafer. Often, a patterned mask such as a photoresist or a hard mask is applied to the surface, and then ion beam etching is used to remove the unmasked material, leaving the masked material.

The ion beam used for such etching inherently has a positive charge. For better processing, the positively charged ion beam is neutralized by the addition of electrons.

### SUMMARY

The present disclosure is directed to an ion beam neutralization system, often referred to as a plasma bridge neutralizer (PBN), as part of an ion beam (etch) system. The system utilizes a filament thermo-electron emitter PBN design, that when utilized in a particular method of operation, greatly extends filament life and minimizes variation in neutralizer operating parameters over long periods of operation. In general, changes in parameters during operation are undesirable as they may affect process performance or yield.

The filament thermo-electron emitter design provides a high flux of low energy electrons effective for neutralizing ion beams, e.g., over 100 mA beam current, across exposed substrates of dimensions of up to 300 mm diameter, including but not limited to 100 mm, 150 mm, and 300 mm diameter. The uniformity of neutralization across the area of the substrate is as important as, if not more so, than the neutralization level at any given location on the substrate. Significant differences in neutralization level, which may result, e.g., from stray and/or non-uniform magnetic fields in the process space, can reduce eventual yield due to deviation in etch results or can cause charge damage. The PBN design enables “full” neutralization of the ions and/or the substrate surface and, in some implementations, provides negative surface charging.

In some implementations, the PBN includes a solenoidal electromagnet to produce an axial magnetic field, and a magnetic field concentrator. The magnetic field thus generated greatly improves the efficiency of the discharge of the low energy electrons from the PBN by guiding the electrons out of the PBN via an exit orifice to the process chamber of the ion beam system. The magnetic field concentrator also inhibits leakage of the magnetic field into the process chamber and surrounding space; leakage of the magnetic field can disturb the degree and uniformity of neutralization of the ion beams within the chamber and/or at the substrate location.

The ion beam system and the PBN described herein can be operated at conditions so that any changes of the filament's physical dimensions, due to, e.g., sputtering and evaporation, are inhibited. Because of minimal (if any) changes to the filament, not only is the filament life longer, the operation parameters for the ion beam system utilizing the filament can be essentially constant over long periods of time.

In one particular implementation, this disclosure provides a broad ion beam system having an ion beam generator providing a wide ion beam of low energy ions, and a filament emitter PBN for providing or generating low energy electrons for neutralizing the low energy ions. The PBN comprises a chamber having a filament therein for creating electrons, a centered discharge orifice for emitting the electrons from the chamber as low energy electrons, a magnetic field generator configured to generate a magnetic field within the chamber parallel to an axis of the PBN, and a magnetic concentrator surrounding the PBN and having an aperture aligned with the centered discharge orifice, the magnetic concentrator inhibiting the magnetic field from exiting the PBN.

In another particular implementation, this disclosure provides a broad ion beam system having a plasma bridge neutralizer (PBN) for generating low energy electrons. The PBN comprises a plasma generation chamber operably connected to a chamber power source, the chamber having an interior volume defined by a wall structure and a floor structure having a centered discharge orifice, an inert gas source operably connected to the interior volume, a filament within the interior volume and operably connected to a filament power source, a solenoidal electromagnet in close proximity to the wall structure of the chamber to generate an axial magnetic field within the interior volume, and a magnetic concentrator surrounding at least a portion of the interior volume and having an aperture aligned with the centered discharge orifice.

In another particular implementation, this disclosure provides a method of providing low energy electrons for an ion beam etching system. The method comprises generating an ion beam in a process chamber, the ion beam having current and a diameter of at least 100 mm, generating electrons from a filament of a plasma bridge neutralizer (PBN), generating a magnetic field within the PBN axially aligned with the filament, extracting low energy electrons from the PBN, the low energy electrons having a current greater than the ion beam current, and retaining the magnetic field within the PBN with a magnetic concentrator around the PBN, so that the magnetic field in the process chamber outside of the concentrator is less than 2 Gauss.

In yet another particular implementation, this disclosure provides a broad ion beam system having a plasma bridge neutralizer (PBN) and an ion source providing a wide ion beam of low energy ions, a filament emitter providing electrons, a solenoidal electromagnet creating a magnetic field parallel to an axis of the PBN, and a magnetic concentrator surrounding most of the interior volume of the PBN and having an aperture aligned with a centered discharge orifice for emitting low energy electrons from the PBN. The magnetic field within the interior volume does not leave PBN due to the concentrator, allowing low energy electrons to freely move into the ion beam without any magnetic disruption of this motion.

In some implementations, the wide ion beam has a diameter of at least 300 mm, in some implementations 500 mm, and the low energy ions have an energy no greater than 300 eV. In some implementations, the PBN provides low energy electrons having an energy no greater than 5 eV. In some implementations, the magnetic field is no greater than 2 Gauss outside of the PBN. In some implementations, the electron motion within the chamber of the system (outside of the PBN) is fully determined by electric fields not from the PBN.

In yet another particular implementation, this disclosure provides another method of providing low energy electrons for an ion beam etching system. The method includes generating an ion beam from a gridded ion source in a chamber by applying a voltage to the grid, the resulting ion beam having a diameter of at least 100 mm, extracting low energy electrons (e.g., having an energy no greater than 5 eV) from a plasma bridge neutralizer (PBN), where the electron current from the PBN is higher than the ion current from the ion source. To produce the lower energy electrons in the PBN, a magnetic field axially aligned with the filament in the PBN is generated; this magnetic field is fully located inside the PBN due to a concentrator surrounding the PBN. Because of the concentrator, the magnetic field is no greater than 2 Gauss in the process chamber outside of the PBN; thus, the magnetic field has little or no influence on the electrons after they leave PBN and the motion of the electrons in the process chamber is determined by the electric field in the process chamber. In some implementations, the voltage applied to the grid is no greater than 300 V and at a current of no less than 50 mA.

The design of the PBN of this disclosure is particularly well adapted for low energy ion beam systems, both for beam geometry and surface neutralization of the substrate that the beam impacts. The design of the PBN of this disclosure is also beneficial for substrate surface neutralization for high energy ion beams.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1 is a schematic cross-sectional side view of an example ion beam etching system with a general plasma bridge neutralizer; FIG. 1A is an enlarged schematic cross-sectional side view of the general plasma bridge neutralizer.

FIG. 2 is a graphical representation of neutralization capabilities of plasma bridge neutralizers.

FIG. 3 is a schematic cross-sectional side view of a plasma bridge neutralizer.

FIG. 4 is a graphical representation of charging potential with a magnetic concentrator in a plasma bridge neutralizer.

FIG. 5A is a schematic diagram of a solenoid showing the magnetic field lines and FIG. 5B is a schematic diagram of a solenoid with a magnetic concentrator showing the magnetic field lines.

FIG. 6 is a schematic diagram of an axially magnetized ring magnet.

FIG. 7 is a schematic cross-sectional side view of another plasma bridge neutralizer.

FIG. 8 is a graphical representation of life performance for a filament in a plasma bridge neutralizer.

### DETAILED DESCRIPTION

This disclosure is directed to an ion beam neutralization system, often referred to as a plasma bridge neutralizer (PBN), an ion beam (etch) system having the PBN incorporated therein, and methods of operating the PBN and the ion beam system. The PBN, which includes a solenoidal electromagnet to produce a magnetic field and a magnetic field concentrator, has an extended filament life due to minimal dimensional changes in the filament over its life. Additionally, minimal dimensional changes over the filament life allow for essentially constant operating parameters of the ion beam system.

The following description provides specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples provided below.

Ion beam etch or etching is a process that utilizes an inert gas plasma (e.g., neon, argon, krypton and xenon) to bombard a substrate with ions and hence remove substrate material. The ion beam etching system extracts positively charged ions from inductively coupled plasma (ICP, also referred to as inductively coupled discharge plasma) and provides them as beams of the ions to the substrate. Some ion beam etching systems include a plasma bridge neutralizer (PBN), which delivers electrons to the positive ions of the ion beam, hence neutralizing the ion beam and the substrate onto which the ions are bombarded. Neutralizing the positive ions also inhibits divergence of the ion beam onto the substrate and dissipates charge build-up on the substrate.

Prior to the systems and methods described herein, there has been a need for an improved broad ion beam neutralization system capable of meeting and exceeding critical ion beam neutralization requirements (e.g., between −4 V and +1 V average charging potential) for ion beams at 100 mA and higher beam current, while maintaining long filament life (e.g., at least 300 hours, at least 500 hours) and during operation of which change in the neutralizer operating parameters are effectively negligible. The systems presented herein meet the desired needs.

There are two main types of broad beam ion beam processing—ion beam etch (IBE) and ion beam sputtering deposition (IBSD) or ion beam deposition (IBD). In IBE, a substrate (e.g., wafer) is directly exposed to at least one ion beam of inert or reactive gas atoms or molecules, and the ions remove material from the substrate. The angle between the beam and the substrate can be between 0 and 90 degrees. In direct IBD systems, the substrate is exposed to at least one beam of ions of the material to be deposited on the substrate. In IBSD, an ion beam is incident on a sputtering target and it is the target material that is deposited on the substrate. Both of IBE and IBSD/IBD can utilize an ion beam neutralization system, e.g., a magnetically enhanced neutralizer.

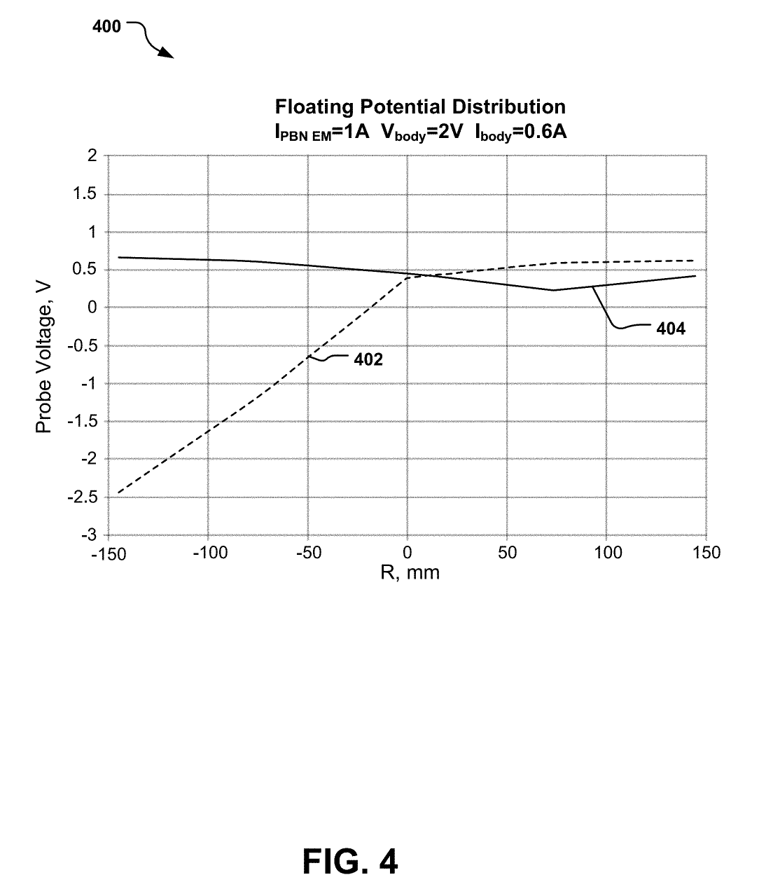

Ion implant plasma, also referred to as ion implant plasma flood, and variations thereof, is a process that also utilizes a magnetically enhanced neutralizer. An example of such a system is provided in U.S. Pat. No. 5,399,871 to Ito et al. Ito et al. describe a neutralization system for ion implantation (see, e.g., FIG. 4 of Ito et al.) that includes a “plasma and low energy electron generator 12” and a “negatively biased electron confinement or guide tube 10.” The electron generator includes a filament-emitter plasma source 22 with an array of axially aligned magnets surrounding the neutralizer walls to produce magnetic fields that, according to Ito et al., “increase the density of the plasma so as to increase the number of electrons produced in the chamber and reduce the average energy level of the electrons. The magnets also increase the rate at which electrons are extracted through the aperture 38 into the guide tube 10.” (Col. 4, lines 38-44 of Ito et al.).

However, ion implant technology such as that of Ito et al. is very different than IBE and IBSD/IBD and has different specific requirements from IBE (see Table 1, below) and what is useful for ion implantation may not be useful for IBE. For example, ion implant systems use a small size beam that is scanned over the substrate, and operate at very low pressure, whereas IBE utilizes a large beam that covers the entire substrate. Other differences are outlined in Table 1.

TABLE 1

| | Ion Beam Etch (IBE, | Ion Implantation |
|---|---|---|
| | IBSD/IBD) low energy | (e.g., Ito et al.) |
| Beam Voltage (V_{b}) | about 100-300 V | about 5-50 kV |
| Beam Current (I_{b}) | about 100-1200 mA | about 0.01-30 mA |
| Neutralizer Current (Iₙ) | about 200-1000 mA | about 10-50 mA |
| Usable Beam diameter | up to 300 mm | about 10 mm |
| | mainly inert gas | dopant beam (e.g., |
| | beam (e.g., Ar) | B₂H₆, PH₃, |
| | | BF₃) |
| Chamber pressure | about 0.2 mTorr | about 0.01 mTorr |
| Plasma electron voltage | about 1.5 eV | about 15 eV |
| PBN Orifice diameter | about 1-7 mm | about 3-15 mm |
| Critical | beam divergence | substrate surface |
| neutralization issue | reduction and | neutralization |
| | substrate surface | |
| | neutralization | |
| | | more complex |
| | | technology |

Returning to Ito et al., the negatively biased guide tube 10 of Itoh et al., which is paramount to the ion implantation process of Ito et al., is a complication and would not be effective or practical for IBE. The level, area, and uniformity of neutralization obtained by the system of Ito et al. would be deficient if applied to IBE, because large area neutralization (e.g., the entire substrate) would be perturbed by the magnetic fields generated by the system.

As indicated above, the PBN ion beam neutralization system, incorporating an improved filament thermo-electron emitter PBN design and, when utilized in a particular method of operation, greatly extends filament life and minimizes variation in neutralizer operating parameters for long periods of operation, while providing a high flux of low energy electrons effective for neutralizing ion beams of over, e.g., 100 mA beam current. Low energy electrons are more effective at neutralizing an ion beam at a given condition than higher energy electrons. These results have been achieved across exposed substrates of dimensions of up to 300 mm diameter and greater. The system also provides “full” neutralization of the substrate and, in some implementations, provides negative surface charging, both at practical long-life operating conditions.

In the following description, reference is made to the accompanying drawing that forms a part hereof and in which are shown by way of illustration at least one specific implementation. In the drawing, like reference numerals may be used throughout several figures to refer to similar components.

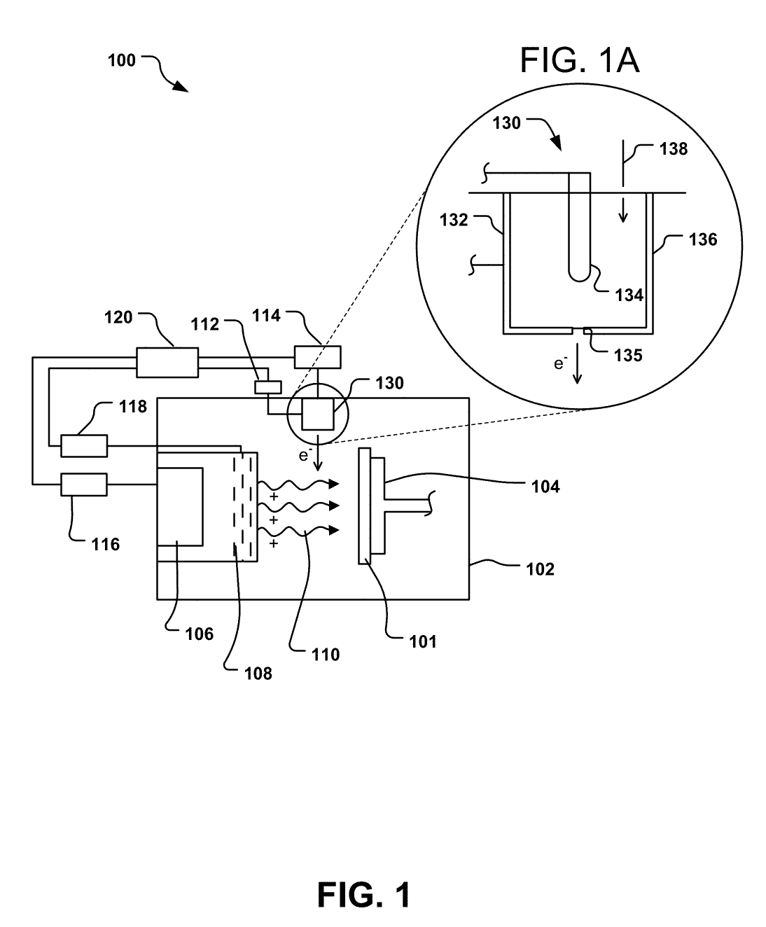

FIG. 1 illustrates schematically a generic ion beam etching system 100. The system 100 has a chamber 102 with a platen 104 for supporting a substrate, such as a wafer 101, e.g., a silicon (Si) wafer, a semiconductor wafer, a sapphire wafer, etc. The platen 104, and the wafer 101, can be configured to rotate about a central axis of the platen 104. Also within the chamber 102 is an ion source 106, configured to emit positively-charged ions. From the ion source 106, the ions pass through a series of grids 108 that collimate the ions into at least one ion beam 110 and optionally steer the beam(s) 110 toward the platen 104 and the wafer 101. Operably connected to the ion source 106 is an RF power source 116 for generating plasma from a gas (not shown; e.g., either an inert gas or a reactive gas) and a beam power source 118 for collimating and steering the ions. Both the RF power source 116 and the beam power source 118 are connected to a process module controller 120 to adjust, maintain, and otherwise control the voltage and/or current from the RF power source 116 and the beam power source 118 to the ion source 106 and the grids 108, respectively. Also within the chamber 102 is a plasma bridge neutralizer (PBN) 130. The PBN 130 provides a stream of low energy electrons (e⁻) for neutralizing the positively-charged ion beam(s) 110 prior to the beam(s) 110 reaching the wafer 101.

Referring to both FIG. 1 and FIG. 1A, the PBN 130 includes an enclosed chamber 132 having therein a filament cathode 134. A filament power source 114 for the filament 134 is connected to the process module controller 120; the filament power source 114, by providing a current through the filament 134, heats the filament 134 so that the filament 134 emits electrons. Ionizing collisions between the emitted electrons and the inert gas atoms from an inlet 138 generate a plasma of ions and low energy electrons. The low energy electrons exit the chamber 132 via a discharge aperture 135 into the system chamber 102 housing the wafer 101. These low energy electrons mix with the positively charged ions from the ion source 106, thus neutralizing the ion beams.

A negative electrical bias (body voltage) on the chamber body 132 of the PBN 130 extracts electrons through the aperture 135. To obtain the negative electrical bias on the chamber body 132, an anode 136, in this implementations the PBN body 132, is connected to a body power source 112 which is connected to the process module controller 120. The process module controller 120 sets the PBN body voltage and controls the PBN body current by adjusting the PBN filament current. The electrons from the filament 134 are accelerated by the PBN discharge voltage.

It should be understood that although a single process module controller 120 is provided in this example for all of the body power source 112, the filament power source 114, the RF power source 116 and the beam power source 118, in other system configurations, multiple controllers may be utilized. Additional details regarding example arrangements for the various power sources for a plasma bridge neutralizer are provided in, e.g., U.S. Pat. No. 8,755,165 to Hansen et al. Additionally, the PBN 130 may have other features, e.g., a cooling jacket around the chamber 132 to control the temperature.

As indicated above, FIG. 1 is a generic schematic of an ion beam system, and a working ion beam system includes other features not illustrated in FIG. 1, such as intake and exhaust systems, a vacuum pump, and other equipment that is generally found in an ion beam system. FIG. 1 merely illustrates generic elements that facilitate the description of the plasma bridge neutralizer.

A plasma bridge neutralizer (e.g., PBN 130) provides low energy electrons that neutralize the positively charged ions in the beam(s) (e.g., ion beam(s) 110) prior to the ion beam(s) impinging upon the substrate (e.g., wafer 101). This prevents divergence of the ion beam(s) and dissipates charge build-up on the substrate. The electron flux or electron flow from the PBN can be controlled based on the ratio of the electron current (Iₙ) and the ion beam current (I_{b}), particularly, K=Iₙ/I_{b}, which is referred to as the K-factor.

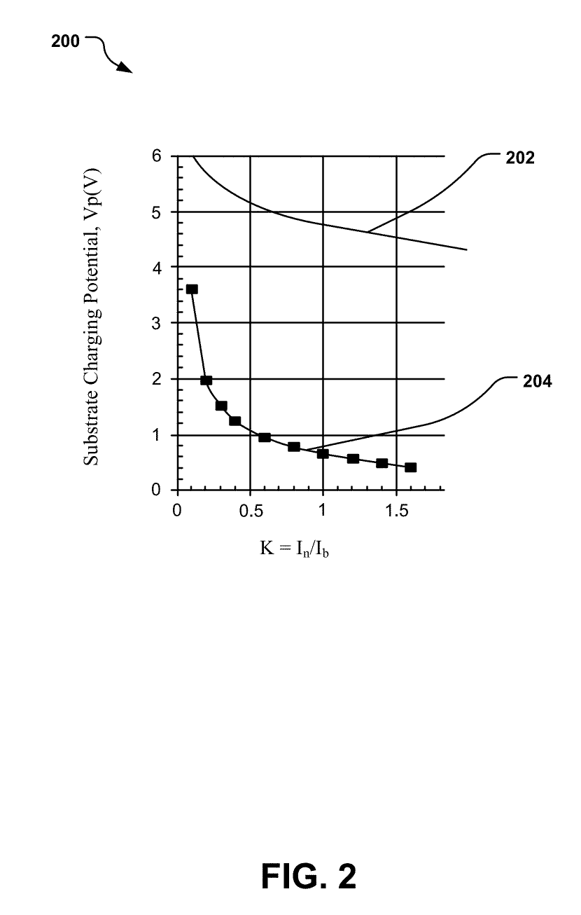

In general, the ion beam is considered “neutralized” when K≥1, but PBNs have different neutralization efficiencies, as shown in graph 200 of FIG. 2. The efficiency of ion beam neutralization is determined by ion beam parameters, such as beam divergence, and the substrate charging potential (e.g., potential of a “floating” (electrically isolated) probe) designated as Vₚ (volts). In general, the lower the Vₚ, the more desired; Vₚ<1 is particularly desirable.

Curve 202 of the graph 200 shows the substrate charging potential (Vₚ) as a function of the K-factor for a typical filament-less PBN, such as a PBN having a glow discharge hollow cathode design; such a PBN has a practical minimum charging potential of about 4-5 V. The charging potential is due to the inherent nature of plasma generation, and can be used for routine neutralization requirements. Curve 204 shows the substrate charging potential (Vₚ) as a function of the K-factor for a typical filament-emitter PBN, such as that of FIG. 1A, which has been optimized for efficient neutralization. Such PBNs can be used for, e.g., ESD-sensitive and other critical neutralization processes. As seen in FIG. 2, the curve 204 provides for a Vₚ<3 V and even Vₚ<1 V, for essentially all shown Ks, particularly, most of which are K<1.5; these charging potentials are not generally obtainable with a filament-less neutralizer.

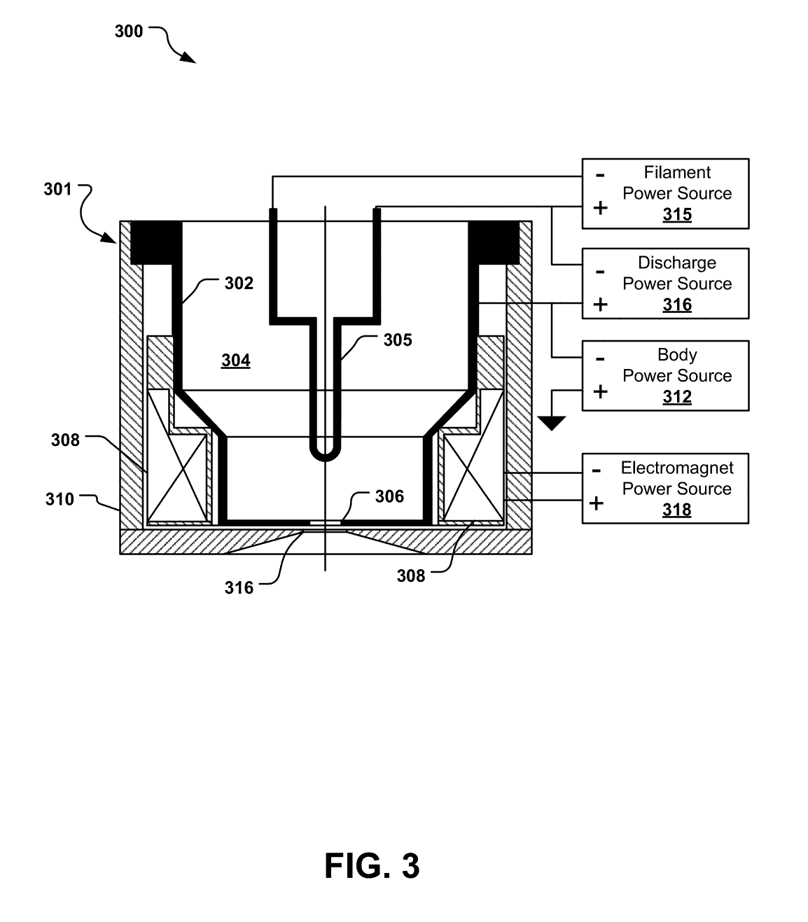

FIG. 3 shows an example filament-emitter PBN 300, in accordance with various features of this disclosure. The PBN 300 has an overall body 301 that has an inner body 302 that forms a chamber 304 that receives an inert gas from a gas inlet (not shown in FIG. 3). Also within the chamber 304 is a filament cathode 305 that, upon heating, emits electrons that are accelerated by discharge voltage and collide with the inert gas atoms, thus producing plasma; such a filament 305 can be referred to as a thermo-emitting filament or a thermo-emitting cathode filament. The chamber 304 includes a discharge orifice 306 through which the low energy electrons exit the chamber 304.

Low energy electrons are more effective at neutralizing a positively charged ion beam (in the process chamber of the system) at a given condition than higher energy electrons. Efficient formation of low energy electrons, however, requires a low PBN body voltage (Vₙ). The PBN 300 of FIG. 3, and variations thereof, produces low energy electrons utilizing a body voltage (Vₙ) of not more than 5 V.

A magnetic field source, such as a solenoidal electromagnet (e.g., an electromagnetic coil) 308, is wrapped around the periphery of the inner body 302 to generate an axial magnetic field within the chamber 304 that interacts with electron trajectories. The electromagnet 308 improves low energy electron production efficiency, reduces the discharge and filament currents, and/or focuses the electron density at the axis to help guide extraction of the electrons out of the chamber discharge orifice 306. In some implementations, the electromagnet 308 may include, e.g., at least 30 turns, in some implementations about 300 turns, although more or less turns may be used.

Surrounding the inner body 302, around at least the periphery and the bottom, is a magnetic concentrator 310 formed from a high permeability magnetic material. The magnetic concentrator 310 has a thickness (e.g., about 0.2 inch) to prevent saturation of the magnetic field from the electromagnet 308 and any field from the filament 305. The magnetic concentrator 310 includes an outlet 316 aligned with the discharge orifice 306 in the chamber body 302 to allow the low energy electrons to leave the PBN 300 and progress to the process space of the ion beam system to neutralize the ion beam(s). The outlet 316 may be, e.g., circular, directional, e.g., elliptical or oval, etc.

The magnetic concentrator 310 concentrates the generated magnetic field along the longitudinal axis of the PBN, along the direction of the filament 305, and inhibits and/or prevents magnetic field lines from exiting the PBN 300 and penetrating the process space of the ion beam system and hence disturbing the degree and uniformity of the ion beam neutralization. This effect is illustrated in FIG. 4, where the variation in substrate charging potential across the beam diameter is observed to be much more uniform with the incorporation of the magnetic concentrator 310 than without a magnetic concentrator. This magnetic concentrator 310 with the outlet 316 provides a consistent neutralization across the entire ion beam being neutralized and hence for the entire substrate.

The graph 400 of FIG. 4 shows the potential across a 300 mm beam. The curve 402, without a magnetic concentrator, shows that the potential (voltage) is essentially constant (level) only for half the beam width, and hence, only half the substrate, whereas the curve 404, with a magnetic concentrator, shows an essentially constant and consistent potential across the entire beam diameter. The curve 404 shows the charging potential across the entire substrate is less than 1 V. In some implementations, the charging potential differs across the substrate by no more than +/−0.7 V. In some examples, the charging potential across the entire substrate is less than 1 V+/−0.7 V.

Returning to FIG. 3, the magnetic concentrator 310 assists the magnetic field generator (e.g., the solenoid electromagnetic 308) to guide electrons out through the orifice 306 and outlet 316, while inhibiting and preferably preventing stray magnetic fields from entering the process chamber, which can cause non-uniform neutralization of the substrate. Additionally, it is believed that the combination of the magnetic concentrator 310 and the electromagnet 308 helps reduce filament wear by orienting and aligning the magnetic field in the chamber 304 along the axis with the filament 305, thus reducing electron losses on the PBN body, thus decreasing required discharge current, and thus decreasing sputtering of the filament 305.

The PBN 300 includes a body (anode) power source 312 operably connected to the body 302, a filament power source 315 operably connected to the filament 305, a discharge power source 316, and an electromagnet power source 318 operably connected to the solenoid electromagnet 308.

In one operating methodology of the PBN 300, the filament power source 315 provides a current (I_{f}) of about 45-90 A, the discharge power source 316 provides a voltage (V_{d}) of about 15-30 Vat a current (I_{d}) of about 2-4.5 A, and the body power source 312 provides a voltage (Vₙ) of about 0-5 V at a current (Iₙ) of about 0.25-2.0 A. These operating parameters are particularly suited for a tungsten filament 305.

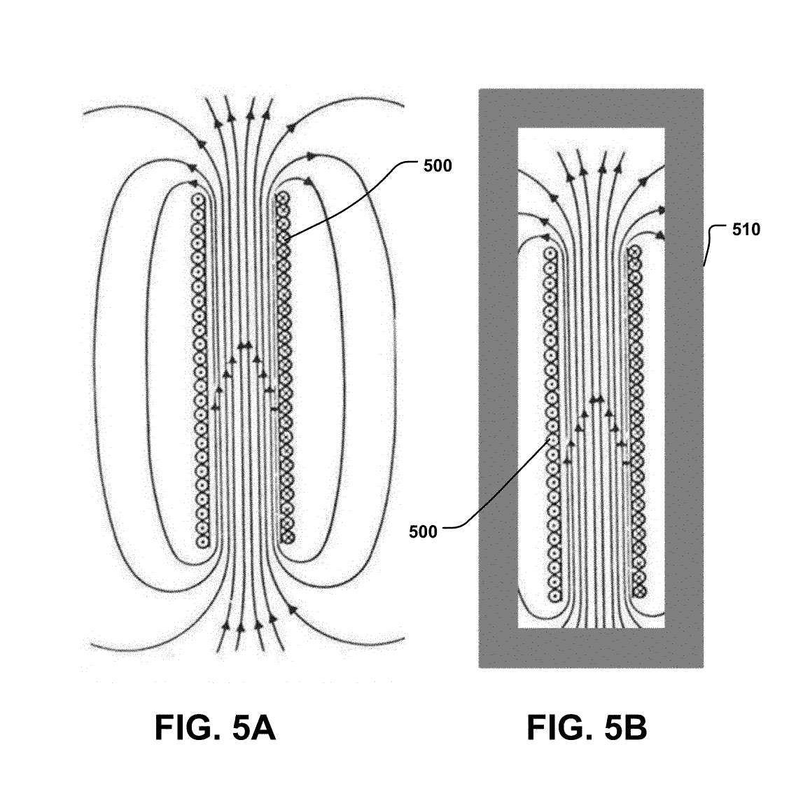

FIGS. 5A and 5B illustrate the benefits of having an electromagnet in the PBN over a permanent magnet.

A solenoidal electromagnet 500, shown in FIG. 5A, creates a strong magnetic field inside the coils parallel to the solenoid axis. The electromagnet 500 has two poles, one at each end face of the solenoid. Magnetic field lines go through solenoid parallel to its axis and exit the end face, go around the electromagnet and come back into the opposite end face.

The magnetic field around the solenoid can be shorted and/or removed by placing a concentrator 510 around the electromagnet 500, as shown in FIG. 5B. With the magnetic concentrator, it is possible to retain the magnetic field inside the solenoid with the magnetic field lines staying parallel to the solenoid axis.

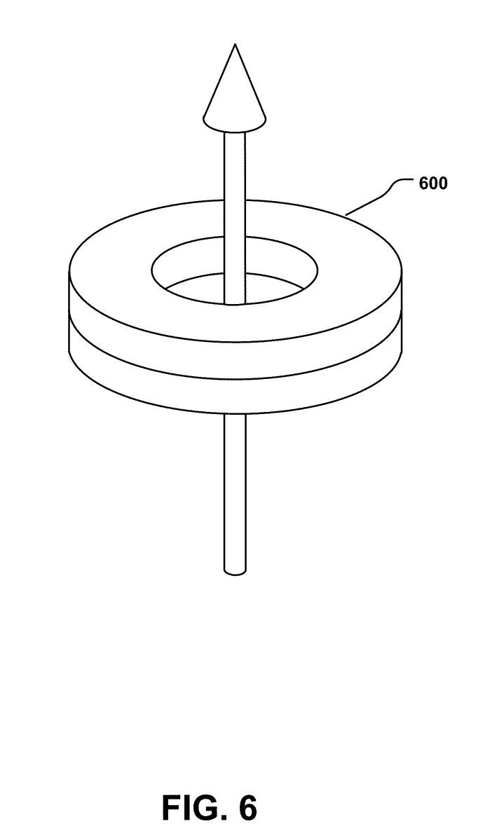

An alternate option to a solenoid is an axially magnetized ring, shown in FIG. 6 as magnet 600. The magnet 600 is a ring-type permanent magnet, axially magnetized. The magnet 600 creates a magnetic field similar to solenoidal electromagnet field shown in FIG. 5A. However, this type of magnet 600 generally cannot be used with a concentrator because the magnetic field would be shorted through the concentrator and the resulting magnetic field inside the magnet 600 would be considerably reduced, in some implementations almost to zero, which is not enough for use in a PBN.

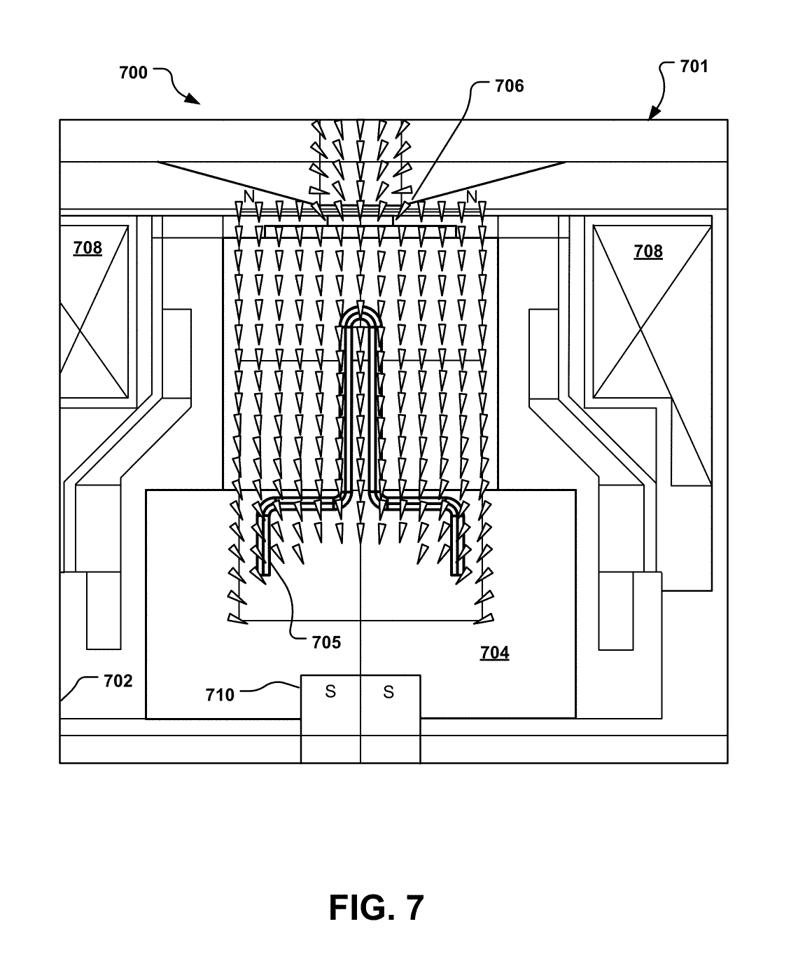

Returning to PBNs, in a similar alternate implementation to the PBN 300 of FIG. 3, FIG. 7 shows an example filament-emitter PBN 700, in accordance with various features of this disclosure. The PBN 700 is illustrated rotated 180 degrees (flipped vertically) in relation to the PBN 300 of FIG. 3. The PBN 700 has an overall body 701 that has an inner body 702 that forms a chamber 704 that receives an inert gas. Also within the chamber 704 is a filament cathode 705 that, upon heating, emits electrons that are accelerated by discharge voltage and collide with the inert gas atoms, thus producing electrons (creating plasma). The chamber 704 includes a chamber discharge orifice 706 through which low energy electrons exit the chamber 704.

As in the PBN 300, a magnetic field source is provided around the chamber 704. In this implementation, the magnetic field source is a solenoidal electromagnet (e.g., an electromagnetic coil) 708 wrapped around the periphery of the chamber 704 together with a permanent magnet 710 at the end opposite the discharge orifice 706. The electromagnet 708 produces a magnetic field inside the chamber 704, improves low energy electron production efficiency, and reduces the discharge and filament currents. The permanent magnet 710 is arranged with its polarity aligned with (e.g., the same as) the polarity of the electromagnet 708. Although not called out in FIG. 7, the PBN 700 includes a magnetic concentrator around the chamber 704.

Such as arrangement increases the density of magnetic field lines within the PBN 700, as shown in FIG. 7, thus creating a mirror effect, also referred to as a magnetic mirror. Particles approaching the end of the PBN 700 proximate the filament 705 and opposite the discharge orifice 706 experience an increasing force that eventually causes them to reverse direction and return to the discharge orifice 706.

The combination of the electromagnet 708 and the permanent magnet 710 significantly reduces losses of electrons within the PBN chamber 704, particularly proximate the filament end. The electromagnet 708 creates a field that prevents electron losses on the walls of the PBN chamber 704 and guides the electrons towards the orifice 706. The permanent magnet 710 reduces electrons losses on the bottom (floor) of PBN chamber 704.

Prior to the designs of the PBNs described herein (e.g., the PBN 300, the PBN 700 and variations thereof) a disadvantage of filament cathodes in ion beam systems was limited filament lifetime. Filament lifetime dictates the mean time between maintenance (MTBM) of the ion beam system, and is based on physical changes occurring to the filament during use of the PBN. A MTBM of 300-500 hours is desired in the semiconductor industry; however, many filaments fall below this desired lifetime. The PBN 300, the PBN 700 and variations thereof, having a solenoid electromagnetic and magnetic concentrator, can readily provide a filament lifetime of at least 500 hours. In some implementations, this filament lifetime is greater than the MTBM of any other components of the ion beam processing system.

As the PBN is operated, the filament is exposed to detrimental sputtering of the inert gas plasma onto the filament and/or evaporation of the filament material due to temperature and charge on the plasma, both which produce changes of the filament physical dimensions. As the filament changes dimension, the filament current (I_{f}) and voltage (V_{f}) change, altering the magnetic field within the PBN due to the altered filament current flow. Changes of less than 10% in a dimension of the filament inhibit changing the physical and energy distribution of the neutralization electrons supplied to the process chamber; however, physical changes greater than 10% change the physical and energy distribution of the low energy neutralization electrons.

In some implementations, a change of 10% of the cross-sectional area of the filament is considered end of the filament lifetime. Thus, filaments with a larger diameter last longer than those with smaller diameters. Conventional plasma sources for semiconductor and related processing use filaments with diameters between 1 to 1.5 mm. Filament diameters larger than 1.5 mm are generally impractical because the current required to achieve operating temperature increases with filament cross-sectional area. Increasing filament length linearly increases electron emission, allowing lower filament temperature, however, it also increases the voltage drop across the filament V_{f}, which increases filament sputtering. A PBN having a magnetic concentrator and an axial field generator addresses many of the issues with filament wear.

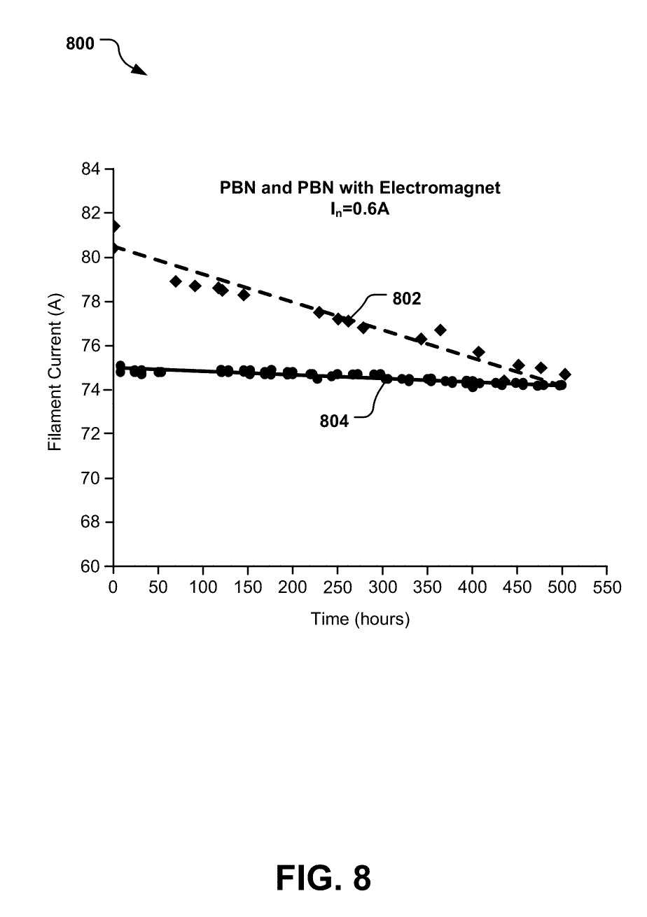

Filament wear is evidenced by a steady decrease in filament current for a source operated at constant electron emission from the PBN; this is a well understood indication of filament wear. FIG. 8 graphically shows the extended filament life that can be obtained with a PBN of this disclosure, such as the PBN 300. No significant wear was observed for over 500 hours operation of a PBN design of this disclosure, e.g., the PBN 300, when operated at selected operating conditions.

The graph 800 in FIG. 8 compares two different PBN configurations, with the curve 802 being for a PBN lacking a magnetic concentrator and an axial field generator, the curve 804 being for a PBN with a magnetic concentrator and an axial field generator.

Curve 804 shows results for a PBN having a magnetic concentrator and an axial magnetic field generator operated at V_{d}=20 V and Vₙ=3 V. These conditions allowed a reduction of filament current (from I_{f} of about 80 A to 75 A), and allowed an operation over 500 hours without significant change in filament operating parameters.

To achieve long filament operation times with effectively no change in operating parameters, having a PBN with a magnetic concentrator and an axial field generator allows the higher discharge efficiency of the magnetically enhanced PBN to operate at conditions where filament wear due to evaporation and sputtering is minimized. To avoid filament wear, depending on the configuration, the energy of the ions (from the inert gas) bombarding the filament cathode is less than the sputter energy threshold and the temperature of the filament is less than the evaporation threshold. Maintaining a low filament temperature can be challenging for filament electron emitters with plasma sources, as both evaporation and electron emission increase exponentially with temperature and the temperature thresholds are not far apart. Although there is no exact threshold for the onset of filament evaporation, an ideal tungsten filament is said to operate at a temperature of about 2400 K whereas plasma sources typically require much higher filament temperatures, e.g., around 2600-2700 K for practical electron emission.

For a PBN having a magnetic concentrator and an axial magnetic field generator, as per the present disclosure, the low energy electron production and the neutralization uniformity can be readily controlled when the PBN has the following features:

Orifice: The size of the discharge orifice from the chamber is 2-9 mm in diameter, in some implementations 5-8 mm. The discharge orifice may be circular or may be oblong (e.g., elliptical or oval); the orifice shape, its orientation, and its position with respect to the filament orientation, position and shape can be designed to increase the efficient of electron extraction and/or the uniformity of neutralization. It was found that for orifices having a larger or smaller diameter than 2-9 mm, the charging potential of the low energy electrons is high.

PBN chamber pressure: The pressure within the PBN chamber, during operation, is about 1-70 mTorr.

Inert Gas (e.g., Ar): The flow of inert gas into the PBN chamber is about 7 sccm in some implementations, in other implementations about 5-10 sccm, to provide a pressure in the chamber of about 0.1-0.4 mTorr, in some implementations about 0.15-0.3 mTorr. In some implementations, a reactive gas (e.g., Kr, Xe) may be used instead of an inert gas.

The calculated range, for inert gas pressure, is 0.001-1 Torr, dependent on the gas flow rate, the discharge orifice size and/or shape, and the chamber pressure. For direct measurements, the chamber pressure is 0.1-0.4 mTorr of inert gas, in some implementations 0.15-0.3 mTorr and insert gas flow rate of 7 sccm (in some implementations 5-10 sccm) for above specified orifice size range.

At low flowrates, typical of conventional PBNs, the charging potential is high. High flowrates are undesirable due to high process chamber pressure and as a result of the high pressure, ion scattering occurs as does dilution of the process gas if the ion source is different from PBN gas.

Magnetic field: A typical magnetic field at the filament tip is about 100 Gauss (for an electromagnet of about 300 A-turns). A discharge efficiency increase is observed when operating in the range of about 10 to 125 Gauss, however, below about 40 Gauss this rate increase drops off.

Electromagnet: The solenoidal electromagnet, at about 300 turns, has a current range about 0.5 A-1.25 A.

In some implementations:

the plasma ion energy is below sputtering threshold (approx. 25 V);

the discharge voltage≤30 V, in some implementations≤20 V, particularly for tungsten and tungsten alloy filaments;

the PBN bias (Vₙ, “body voltage”) is <5 V, in some implementations<3 V;

additionally or alternately, the PBN body voltage with respect to ground, is <−5 V, in some implementations<−3 V;

the filament voltage is <5 V, in some implementations<3 V;

the filament evaporation rate is ‘negligible’;

temperature for a tungsten filament is <2640K;

for a tungsten or tungsten alloy filament, the filament current “I_{f}” and diameter “d” relationship is I_{f}/d^{3/2}<65 A/mm^{3/2}; in an example, d=1.25 mm (0.05 inch), I_{f}(max)=90 A; other examples, the filament has a diameter between 1 mm (0.04 inch) and 1.5 mm (0.06 inch);

there is a neutralization uniformity over a substrate having a diameter of at least 150 mm; and

full neutralization has a charging potential 0 V+/−0.7 V.

Thus, the disclosure herein provides various implementations of ion etch systems, ion beam neutralization systems (PBNs), and various methods. In addition to all described above, the disclosure also provides systems wherein:

In some implementations, a change in filament operating characteristics is indicated by a change in the PBN filament current when the PBN is operated at constant emission and/or discharge current. An “effective change in filament current” is a change of >10%. In some implementations, the PBN filament has essentially no change in its physical dimensions. In some implementations, this occurs when the maximum energy of the ions bombarding the filament is at or below the sputtering threshold of the filament material and the maximum temperature of the filament is at or below the threshold for evaporation for that filament material.

In some implementations, the pressure inside the PBN is between 2 mTorr and 1 Torr, inclusive, the PBN has a discharge orifice diameter that is between 2 and 9 mm, inclusive, in other implementations between 5 and 8 mm, inclusive, with the ion beam system having a process chamber pressure of 0.1 to 0.4 mTorr, in some implementations of 0.15 to 0.3 mTorr, together with a mass flow rate of the inert gas (e.g., Ar) to the PBN of about 5-10 sccm. In some implementations, the average energy of the low energy electrons from the PBN is <5.5 eV and in some implementations<3 eV.

As indicated above, the PBN, in operation, has an axial magnetic field therein and a magnetic concentrator. In some implementations, the axial magnetic field, created by the electromagnet, at the PBN filament, is at least 10 Gauss, and in some implementations about 100 Gauss.

Further provided herein is a PBN system for broad ion beam high vacuum processing equipment, the PBN system used to control beam divergence, beam steering, and substrate surface neutralization. The PBN system has a filament thermo-electron emissive driven plasma generator and a means for adjusting the PBN filament current, discharge voltage and body voltage, and a gas input to the PBN. The means for adjusting the PBN filament current, discharge voltage and body voltage may be one or more controllers. The plasma containment chamber has a central axis on which the filament is located at one end and an orifice allowing gas outflow and electron emission to the ion beam processing chamber at the opposite end. In some implementations, the PBN has a water-cooled plasma containment chamber.

The PBN system, in some implementations, includes a means for generating a magnetic field along the axis of the PBN, and a means for concentrating the magnetic field inside the body of the PBN. The means for generating the magnetic field can be a solenoidal electromagnetic coil concentric with the axis of the PBN chamber, where the number of turns and current rating of the coil is sufficient to generate a magnetic field at the electron discharge orifice of at least 10 Gauss, and in some implementation at least 100 Gauss. The means for concentrating the magnetic field, which can also be referred to as a magnetic field concentrator, is a shroud of magnetically permeable material enclosing the body or chamber of the PBN except the body orifice area and the end at which the filament is mounted.

Also provided herein is a method of ion beam neutralization of a substrate in a broad ion beam materials processing system, the method utilizing an ion beam of greater than 100 mA and utilizing a filament-emitter driven plasma bridge neutralizer (PBN) electron source capable of achieving a planar substrate charging potential of less than −0 V, and in some implementations<−3V, across the area of the substrate, and operable at this condition for at least 300 hours.

Another method provided herein is a method of ion beam neutralization of a substrate in a broad ion beam materials processing system, utilizing a filament-driven plasma bridge neutralizer (PBN) electron source, operated to neutralize an ion beam current of at least 100 mA by an electron current at least equal to the ion beam current for an average cumulative operating time of at least 300 hours, wherein the PBN filament effectively does not change its operating characteristics over the operating time.

The above specification and examples provide a complete description of the process and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about.” Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, “on top”, etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

1. A broad ion beam system comprising:
an ion beam generator for providing a beam of ions; and
a plasma bridge neutralizer (PBN) for generating low energy electrons, comprising:
a plasma generation chamber operably connected to a chamber power source, the chamber having an interior volume defined by a wall structure and a floor structure having a entered chamber discharge orifice for extracting the electrons from the PBN chamber as low energy electrons;
an inert gas source operably connected to the interior volume;
a thermo-emitting cathode filament within the interior volume and operably connected to a filament power source;
a magnetic field generator configured to generate a magnetic field within the chamber parallel to an axis of the PBN; and
a magnetic concentrator surrounding the chamber and having an aperture aligned with the chamber discharge orifice, the magnetic concentrator inhibiting the magnetic field from exiting the PBN.

2. The broad ion beam system of claim 1, wherein the magnetic field generator is a solenoidal electromagnet.

3. The broad ion beam system of claim 1, wherein the ion beam is a wide ion beam having a diameter of at least 300 mm.

4. The broad ion beam system of claim 3, wherein the ions from the wide ion beam generator are low energy ions.

5. The broad ion beam system of claim 4, wherein the low energy ions have a voltage of no greater than 300 eV.

6. The broad ion beam system of claim 1, wherein the low energy electrons have a voltage no greater than 5 eV.

7. The broad ion beam system of claim 6, wherein the low energy electrons have a voltage less than 3 eV.

8. The broad ion beam system of claim 1, wherein the magnetic concentrator inhibits the magnetic field from exiting the PBN allowing the low energy electrons to freely move into the ion beam without magnetic disruption.

9. The broad ion beam system of claim 1, wherein the magnetic field outside of the PBN is no greater than 2 Gauss.

10. The broad ion beam system of claim 1, wherein electron motion in the chamber is fully determined by the electric field.

11. The PBN of claim 1, wherein the magnetic concentrator is exterior to the wall structure and the floor structure.

12. The PBN of claim 11, wherein the magnetic concentrator is continuous around the wall structure.

13. The PBN of claim 11, wherein the magnetic field is parallel to the filament.

14. A method of providing low energy electrons for an ion beam etching system, the method comprising:
generating an ion beam in a process chamber, the ion beam having a current and a diameter of at least 100 mm;
extracting low energy electrons from a plasma bridge neutralizer (PBN) having a filament, the low energy electrons having a current greater than the ion beam current;
generating a magnetic field within the PBN axially aligned with the filament; and
retaining the magnetic field within the PBN with a magnetic concentrator around the PBN, so that the magnetic field in the process chamber outside of the concentrator is less than 2 Gauss.

15. The method of claim 14, wherein the ion beam is a low energy ion beam having a voltage no greater than 300 eV.

16. The method of claim 14, wherein the low energy electrons have a voltage no greater than 5 eV.

17. The method of claim 16, wherein the low energy electrons have a voltage less than 3 eV.

18. The method of claim 14, wherein generating the ion beam comprises generating the ion beam from a gridded ion source.

19. The method of claim 18, wherein generating the ion beam from a gridded ion source comprises generating the ion beam by applying a voltage of no greater than 300 V to a grid at a current of no less than 50 mA.

20. The method of claim 14 further comprising emitting the low energy electrons from the PBN through a chamber orifice aligned with the magnetic field.

21. The method of claim 20, wherein the low energy electrons are emitted as a beam having a diameter of at least 100 mm.

22. The method of claim 21, wherein the low energy electrons are emitted as a beam having a diameter of 100 to 500 mm.

23. The method of claim 14 further comprising maintaining a pressure of 0.1 to 0.5 mTorr in the process chamber.
